(19) United States
(12) Patent Application Publication
(10) Pub. No.: US 2016/0315084 A1
(43) Pub. Date: Oct. 27, 2016

(54) DIFFERENT HEIGHT OF FINS IN SEMICONDUCTOR STRUCTURE

(71) Applicant: GLOBALFOUNDRIES INC., Grand Cayman (KY)

(72) Inventors: Xusheng WU, Ballston Lake, NY (US); HongLiang SHEN, Ballston Lake, NY (US); Changyong XIAO, Mechanicville, NY (US); Jianhua YIN, Mechanicville, NY (US); Jie CHEN, Mechanicville, NY (US); Jin Ping LIU, Ballston Lake, NY (US); Hong YU, Rexford, NY (US); Zhenyu HU, Clifton Park, NY (US); Lan YANG, Ballston Lake, NY (US); Wanxun HE, Rexford, NY (US)

(73) Assignee: GLOBALFOUNDRIES INC., Grand Cayman (KY)

(21) Appl. No.: 14/691,960

(22) Filed: Apr. 21, 2015

(51) Int. Cl. H01L 27/092; H01L 29/10; H01L 21/8238

(52) U.S. Cl. CPC H01L 27/0924; H01L 21/823878; H01L 29/1033

(57) ABSTRACT

There is set forth herein in one embodiment a semiconductor structure having a first region and a second region. The first region can include fins of a first fin height and the second region can include fins of a second fin height.

### TECHNICAL FIELD

The present invention relates to a semiconductor fin structure and more particularly a FinFET semiconductor structure having fins of different fin heights.

### BACKGROUND OF THE INVENTION

According to a FinFET semiconductor structure architecture, fins can be formed that extend upwardly from a substrate main body. In one commercially available form, a substrate can have various sections recessed to define fins so that fins extend contiguously from the substrate main body. In one commercially available form fins of a FinFET semiconductor structure can be formed of a material that is different from a material of a substrate on which the fins are formed. In one commercially available form a SOI semiconductor wafer can be provided and fins can be patterned on a silicon (Si) top layer of the SOI wafer. FinFET semiconductor structures can have one or more active region. An active region can include one or more fins. Active regions of a semiconductor structure can be separated by isolation regions. In one commercially available form, trenches can be provided at the isolation regions.

Commercially available FinFETs can be formed in part of silicon. Alternative materials have been proposed for fabrication of FinFETS. In one aspect alternative materials can feature improved mobility over silicon. Semiconductor structures having germanium (Ge) or III-V materials have been proposed.

### BRIEF DESCRIPTION

There is set forth herein in one embodiment a semiconductor structure having a first region and a second region. The first region can include fins of a first fin height and the second region can include fins of a second fin height.

### BRIEF DESCRIPTION OF THE SEVERAL VIEWS OF THE DRAWINGS

One or more aspects of the present invention are particularly pointed out and distinctly claimed as examples in the claims at the conclusion of the specification. The foregoing and other objects, features, and advantages of the invention are apparent from the following detailed description taken in conjunction with the accompanying drawings in which:

FIG. 1 is a perspective view of a semiconductor structure;

FIG. 2 is a side view of a semiconductor structure having a substrate, a dielectric layer and a hard mask layer;

FIG. 3 is a side view of a semiconductor structure in an intermediary stage of fabrication after removal of material from a certain region;

FIG. 4 is a side view of a semiconductor structure in an intermediary stage of fabrication after forming of a dielectric layer;

FIG. 5 is a side view of a semiconductor structure in an intermediary stage of fabrication after forming of layers for performance of sidewall image translation;

FIG. 6 is a side view of a semiconductor structure in an intermediary stage of fabrication after patterning of mandrels and formation of a layer defining sidewalls over patterned mandrels;

FIG. 7 is a side view of a semiconductor structure in an intermediary stage of fabrication after patterning of formations for use in defining fins;

FIG. 8 is a side view of a semiconductor structure in an intermediary stage of fabrication after patterning of formations for use in defining fins;

FIG. 9 is a side view of a semiconductor structure in an intermediary stage of fabrication after recessing of material of a substrate for defining fins;

FIG. 10 is a side view of a semiconductor structure in an intermediary stage of fabrication after formation of a dielectric layer;

FIG. 11 is a side view of a semiconductor structure in an intermediary stage of fabrication after recessing of a dielectric layer;

FIG. 12 is a side view of a semiconductor structure in an intermediary stage of fabrication after pattering of gate structures;

FIG. 13 is a side view of a semiconductor structure having a substrate, a dielectric layer and a hard mask layer;

FIG. 14 is a side view of a semiconductor structure in an intermediary stage of fabrication after patterning of formations for use in patterning fins;

FIG. 15 is a side view of a semiconductor structure in an intermediary stage of fabrication after patterning of fins;

FIG. 16 is a side view of a semiconductor structure in an intermediary stage of fabrication after removal of material of a dielectric later and a hard mask layer and after formation of a dielectric layer;

FIG. 17 is a side view of a semiconductor structure in an intermediary stage of fabrication after formation of a mask layer for use in recessing a dielectric layer;

FIG. 18 is a side view of a semiconductor structure in an intermediary stage of fabrication after removal of a mask layer and after recessing of a dielectric layer; and

FIG. 19 is a side view of a semiconductor structure in an intermediary stage of fabrication after patterning of gate structures.

### DETAILED DESCRIPTION

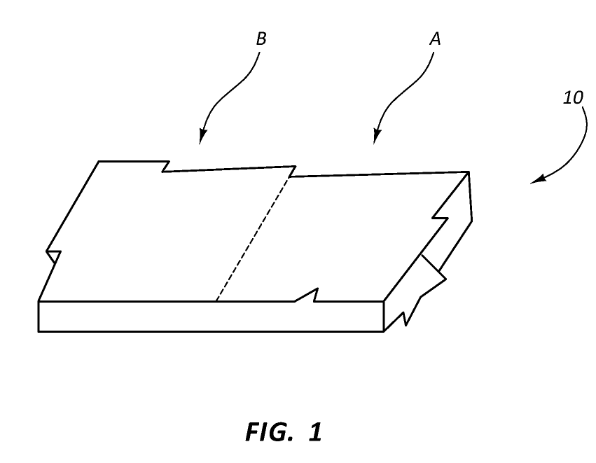

Referring to FIG. 1 there shown a semiconductor structure 10. Semiconductor structure 10 can include a first region, region A and a second region, region B. Each of region A and region B can include fins. In one aspect fins of region A can have a different height than fins of region B. On the fins of each region there can be formed field effect transistors (FETs).

In one embodiment, region A can include FETs of a first polarity and region B can include FETs of a second polarity opposite of the first polarity. In such an embodiment, nFET and pFET regions can be provided that include device variability (mismatch) characteristics that have a higher level of correspondence to one another than would be provided in the case FETs of region A and region B include common fin heights.

In one embodiment, region A and region B can be of a common polarity, e.g., each of region A and region B be nFET regions or in the alternative each of region A and region B can be pFET regions. In one example of such embodiment different fin heights throughout the regions can be included to provide a tuning knob for tuning of threshold voltage, Vt.

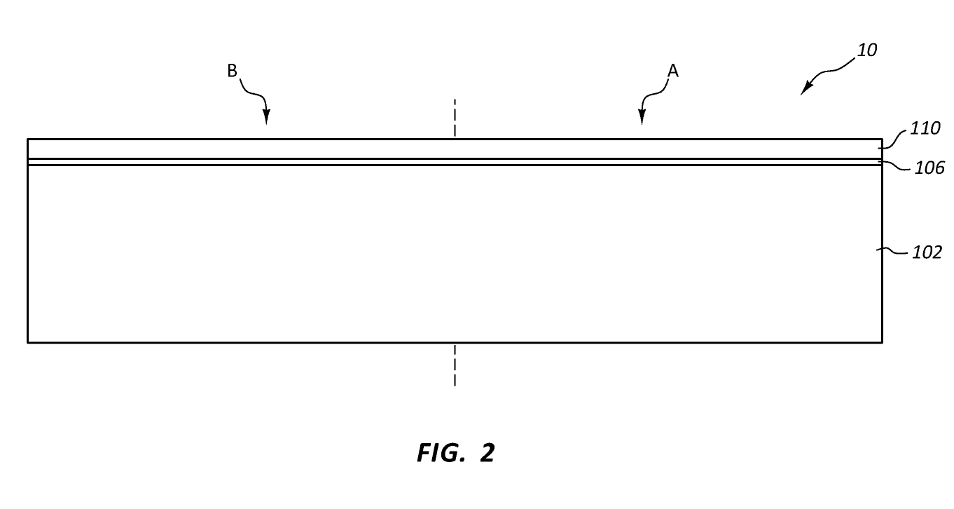

An example of a method for providing a semiconductor structure having different fin heights is set forth in reference to FIGS. 2-11.

Referring to FIG. 2, semiconductor structure 10 can include a substrate 102. There can be formed on substrate 102 layer 106 and layer 110. Substrate 102 can be formed of Silicon (Si), layer 106 can be a pad oxide layer and layer 110 can be a hard mask layer formed of, e.g., silicon nitride (SiN).

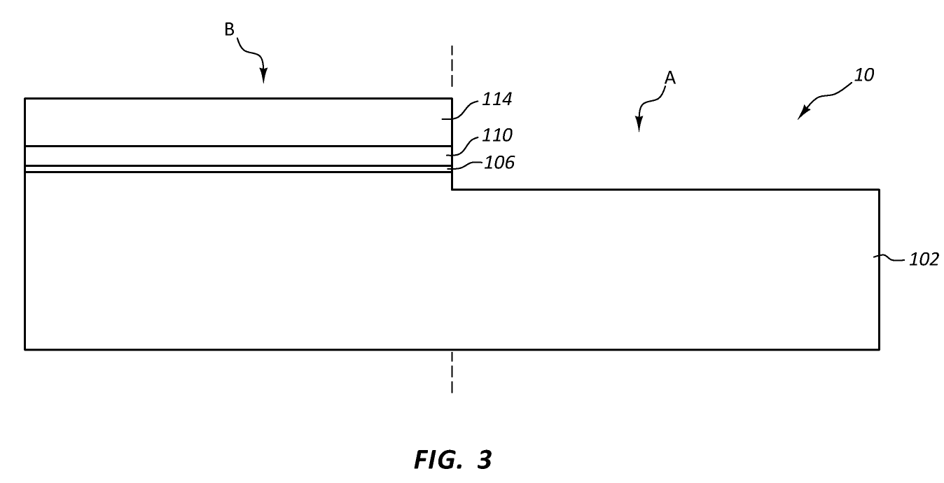

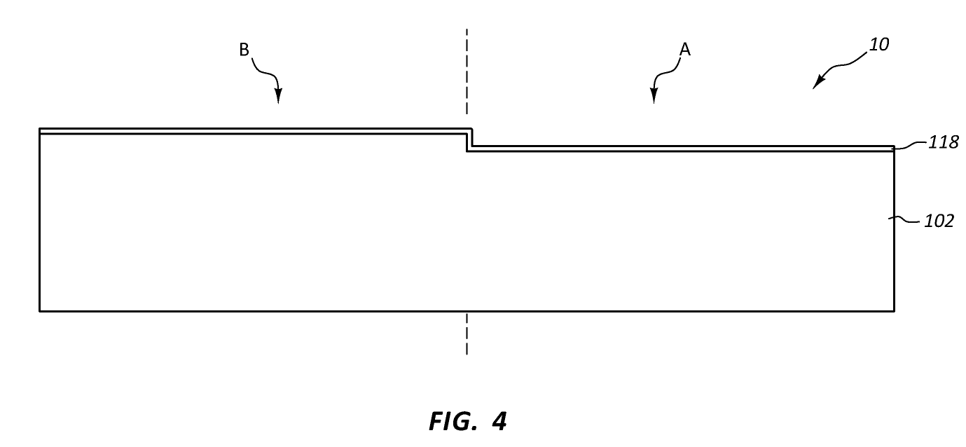

FIG. 3 illustrates semiconductor structure 10 as shown in FIG. 2 after patterning of substrate 102 to reduce an elevation of substrate 102 within region A. As shown in FIG. 3, layer 114 which can be a masking layer, can be applied over region B and substrate 102, as well as layer 106, and layer 110 can be etched within region A. Referring to FIG. 4, layer 106, layer 110, and layer 114 can be removed from substrate 102 within region B and layer 118 which can be pad oxide layer, can be formed on substrate 102 throughout region A and region B.

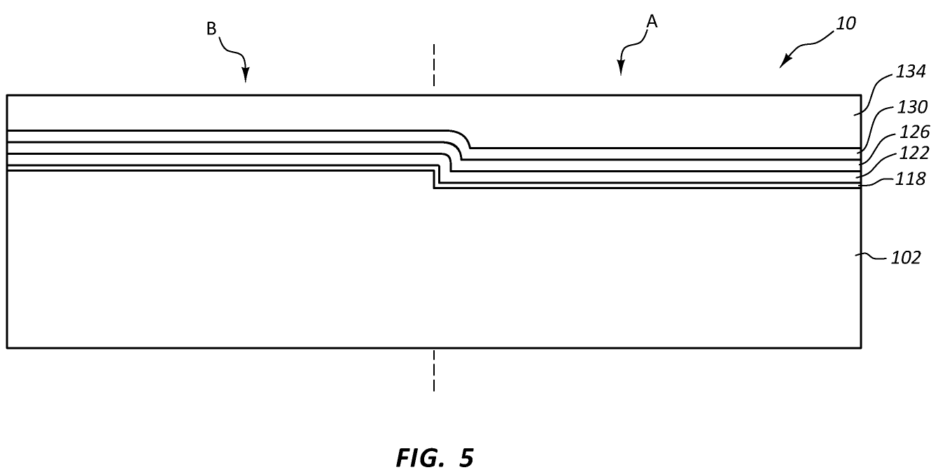

Referring now to FIGS. 5-10, sidewall image transfer (SIT) processes can be used for the formation of fins. Use of SIT processes can facilitate formation of narrow width fins, e.g., on the order of 20 nm or less.

FIG. 5 illustrates semiconductor structure 10 as shown in FIG. 4 after formation of layer 122, layer 126, layer 130, and layer 134. Layer 122 can be formed of hard mask material (e.g. formed of SiN). Layer 126 can be formed of dielectric material, e.g. formed of oxide. Layer 130 can be formed of amorphous silicon. Layer 134 can be a mandrel layer for use in formation of mandrels. Layer 134 can be formed of spin on hard mask (SOH) material.

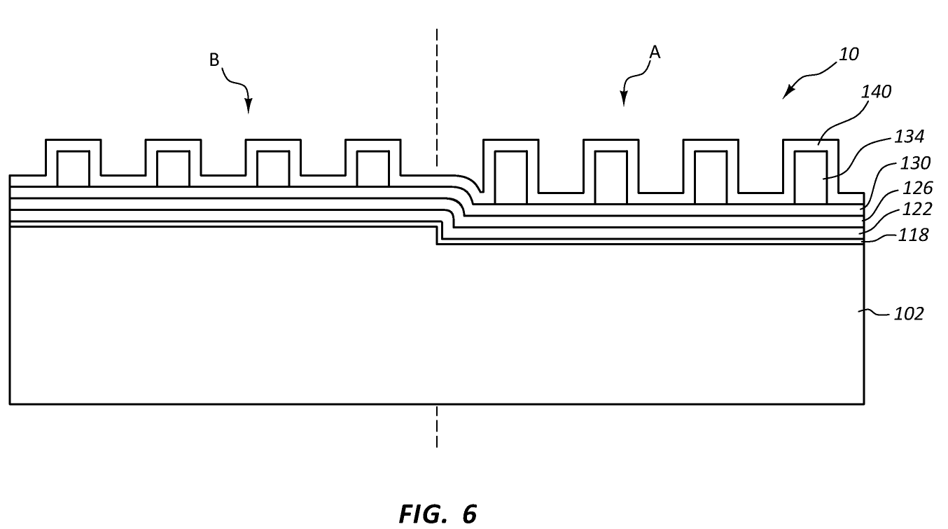

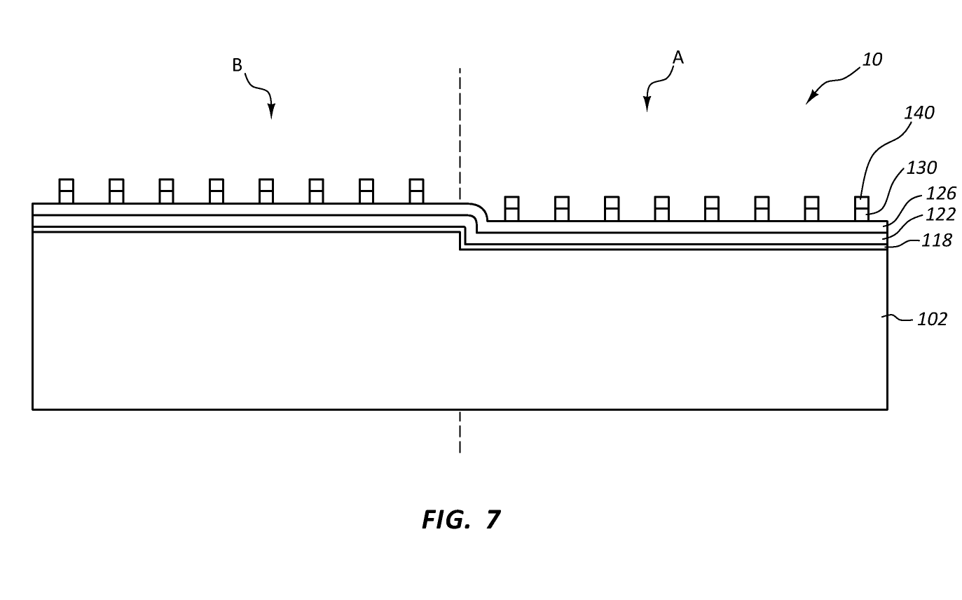

FIG. 6 illustrates semiconductor structure 10 as shown in FIG. 5 after patterning of mandrels defined by layer 134 and further after formation of layer 140. Layer 140 can be formed of dielectric material, e.g. oxide. FIG. 7 illustrates the semiconductor structure 10 as shown in FIG. 6 after patterning of layer 130 using sidewalls as shown in FIG. 6 defined by layer 140.

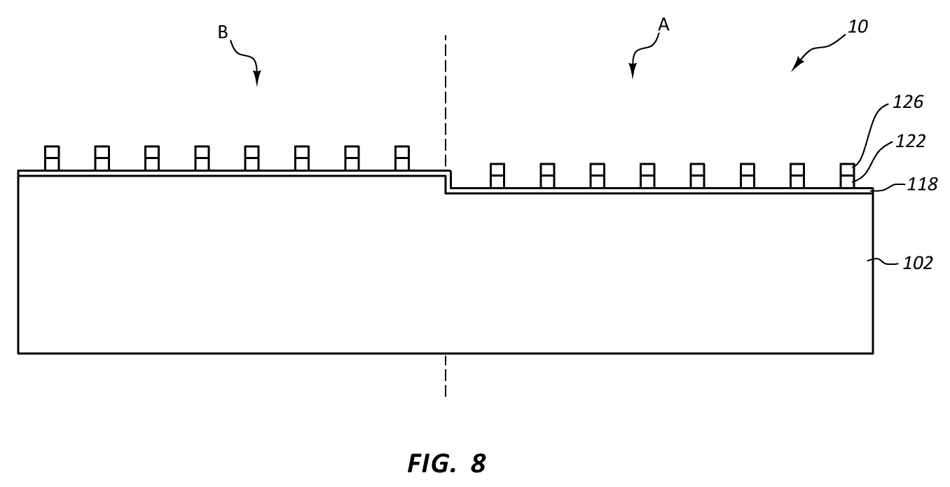

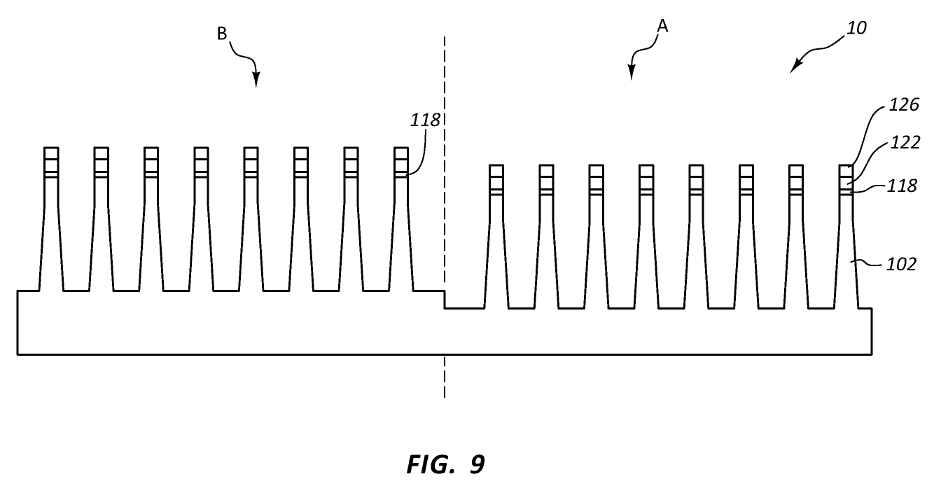

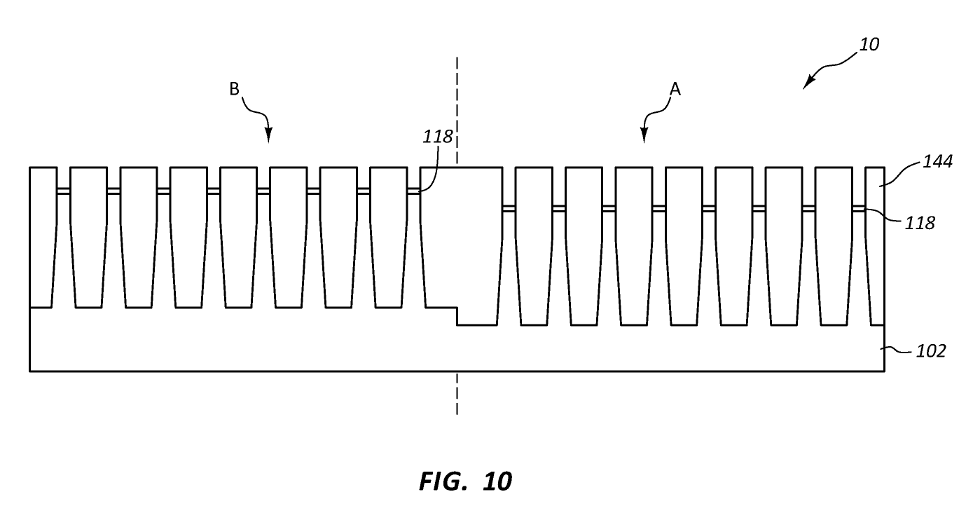

FIG. 8 illustrates the semiconductor structure 10 as shown in FIG. 7 after patterning of layer 126 and layer 122 using the pattern defined by layer 130 and layer 140 as shown in FIG. 7. FIG. 9 illustrates the semiconductor structure 10 as shown in FIG. 8 after patterning substrate 102 using a pattern defined by layer 122 and layer 126 as shown in FIG. 8. FIG. 10 illustrates the semiconductor structure 10 as shown in FIG. 9 after planarization of layer 144 and removal of layer 122.

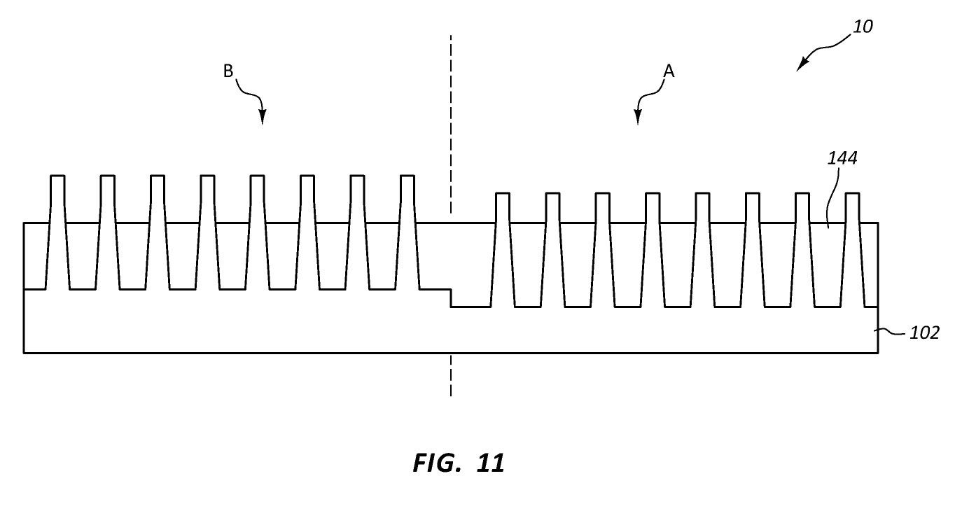

FIG. 11 illustrates the semiconductor structure 10 as shown in FIG. 10 after recessing of layer 144 so that a top elevation of layer 144 is below a top elevation of substrate 102.

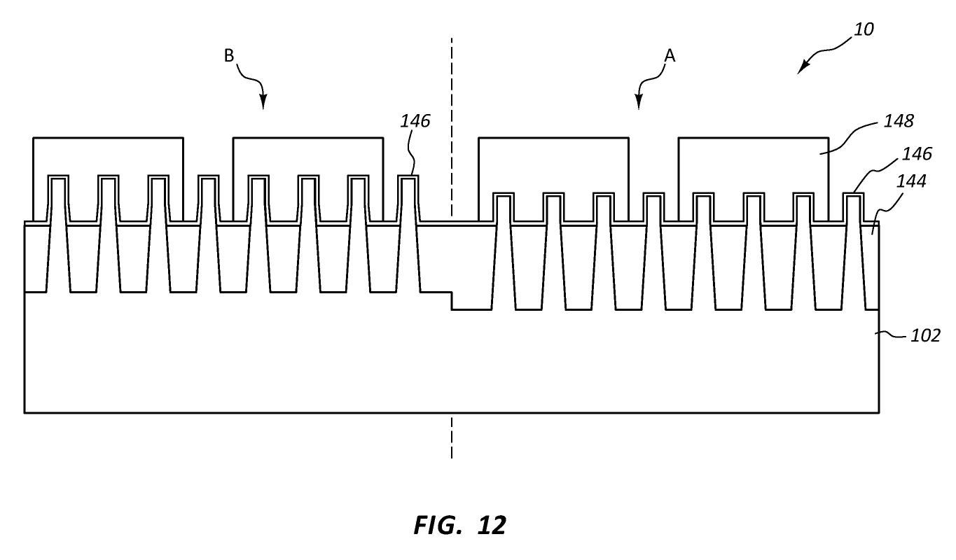

FIG. 12 illustrates the semiconductor structure 10 after formation of layer 146 and layer 148. Layer 146 can be formed of dielectric material, e.g. oxide. Layer 146 can be a thin oxide layer, e.g. about 2 nm to about 5 nm. Layer 148 can be formed of polysilicon. Layer 148 can be patterned as shown in FIG. 12 to define gate structures. Gate structures defined by layer 148 can be e.g. polysilicon gates or sacrificial polysilicon gates. Layer 146 and layer 144 can be of a common dielectric material. Layer 146 and layer 144 can be of different dielectric materials.

Referring to the semiconductor structure as shown in FIG. 12, the fins of region A and region B can include respective first and second different fin heights. Region A can have a first fin height and region B can have a second fin height. In the embodiment of FIG. 12, a fin height can be regarded as the spacing distance between a top elevation of layer 144 which can be a dielectric layer and a top elevation of substrate 102. In the embodiment of FIG. 12, fins within region B can have a higher top elevation than fins of region A. In the embodiment of FIG. 12, layer 144 can have a common top elevation through region A and region B. Fins within region A as shown in FIG. 12 can have a first height. Fins within region B as shown in FIG. 12 can have a second height greater than the first height.

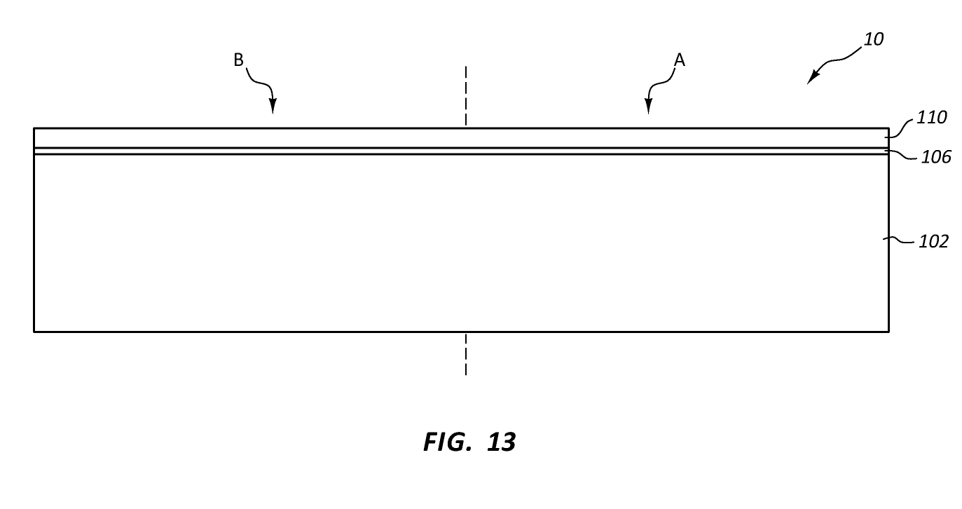

Another method for fabrication of a semiconductor structure 10 having regions of different fin heights is described with reference to FIGS. 13-19.

A starting semiconductor structure 10 having the configuration of the semiconductor structure 10 as shown in FIG. 2 is illustrated in FIG. 13. In FIG. 13 there is illustrated a starting semiconductor structure 10 having a substrate 102, layer 106, and layer 110. Substrate 102 can be formed of Silicon (Si), layer 106 can be a pad oxide layer and layer 110 can be a hard mask layer, e.g., a nitride hard mask layer formed of silicon nitride (SiN).

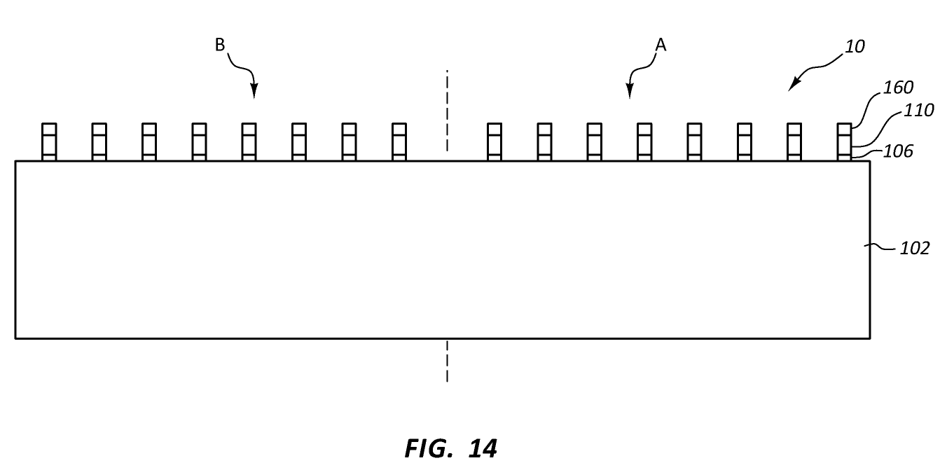

FIG. 14 illustrates the semiconductor structure 10 as shown in FIG. 13 after patterning of layer 106 and layer 110. Referring to FIG. 14, layer 160 can be formed of masking material. Referring to FIG. 14, layer 160 can be a masking layer for use in patterning layer 106 and layer 110. The formation defined by patterned layers 106, 110 and 160 as shown in FIG. 14 can be used to pattern fins.

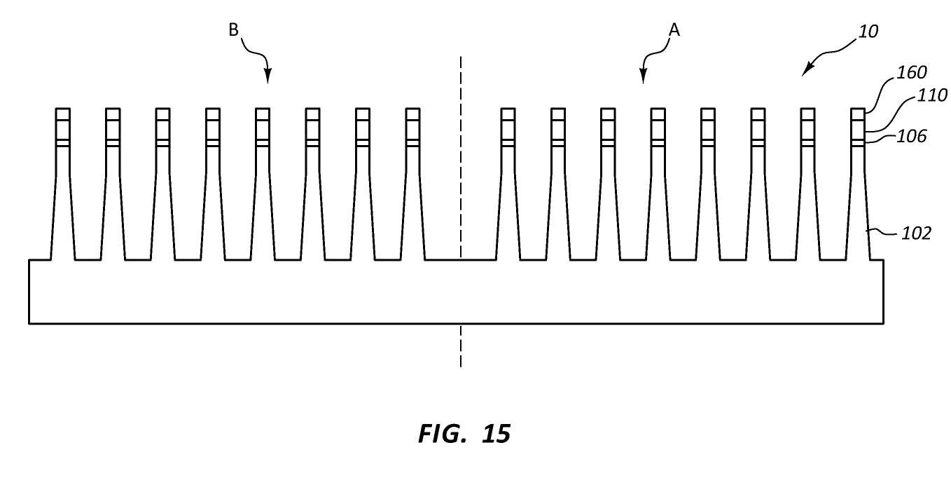

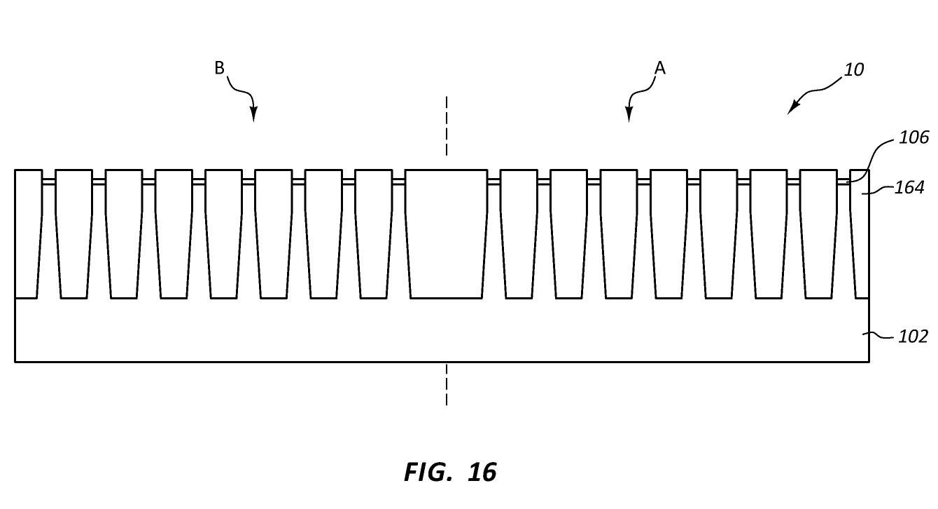

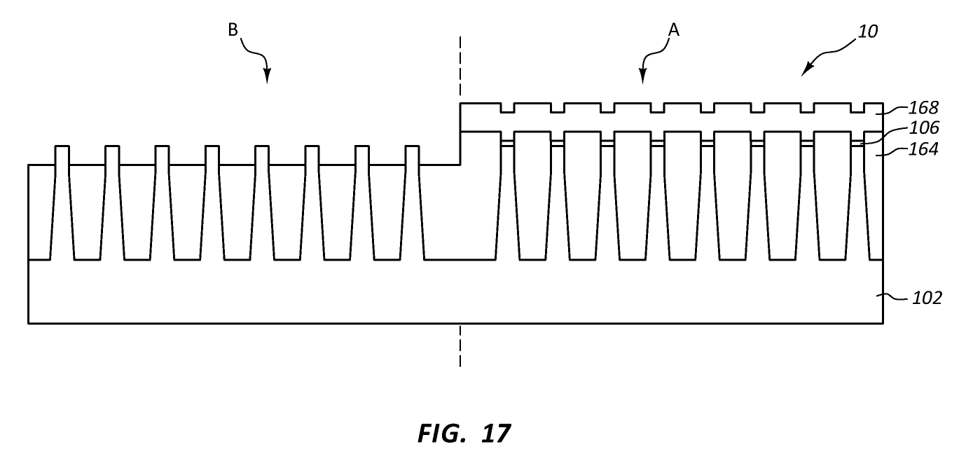

FIG. 15 illustrates the semiconductor structure 10 as shown in FIG. 14 after removal of material of layer 102 so that fins are defined by layer 102. FIG. 16 illustrates the semiconductor structure 10 as shown in FIG. 15 after formation of layer 164 to fill trenches defined by fins that are defined by layer 102 as shown in FIG. 15 and after removal of material of layer 110 and layer 160. FIG. 17 illustrates the semiconductor structure 10 as shown in FIG. 16 after formation of layer 168 over region A. Layer 168 can be formed of masking material. Layer 168 can be a masking layer. As illustrated in FIG. 17, with layer 168 formed over region A, layer 164 can be reduced in elevation within region B.

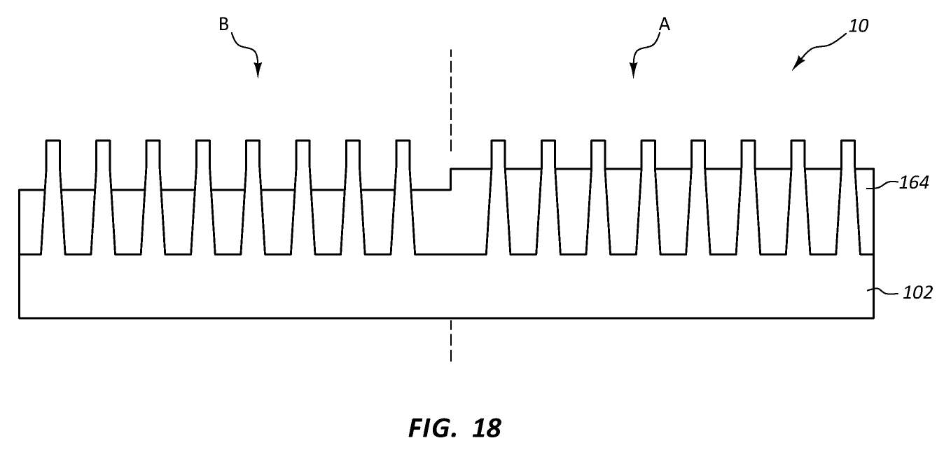

FIG. 18 illustrates the semiconductor structure 10 as shown in FIG. 17 after removal of layer 168 and after recessing of layer 164 within each of region A and region B. As shown in FIG. 18 semiconductor structure 10 can include fins within region A and region B. The height of fins between region A and region B can be differentiated. The height of fins between region A and region B can be regarded as the spacing distance between top elevation of layer 164 (formed of dielectric, e.g. oxide material) and a top elevation of the fins defined by substrate 102 (formed e.g. of silicon). It is seen in reference to FIG. 18 that with fin height defined as the vertical spacing between the top elevation of substrate 102 and a top elevation of layer 164 a height of fins within region B embodiment of FIG. 18 is larger in region B relative to region A.

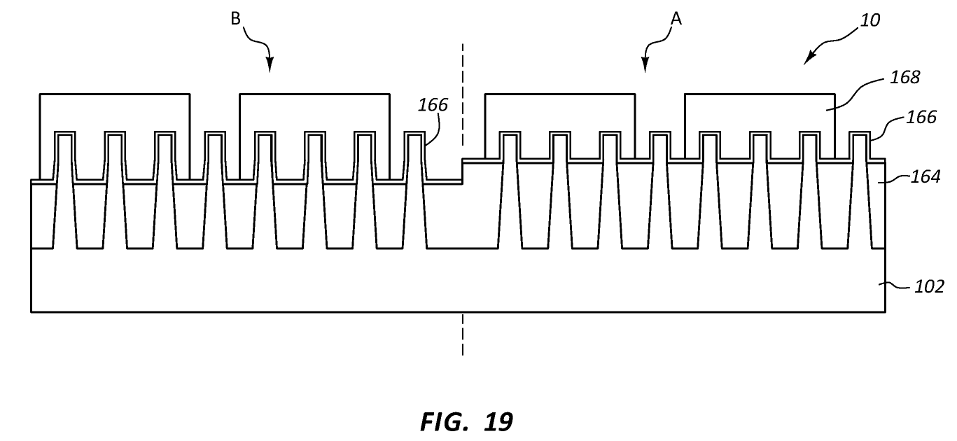

FIG. 19 illustrates the semiconductor structure 10 as shown in FIG. 18 after formation of layer 166 and layer 168. Layer 166 can be formed of dielectric material, e.g. oxide. Layer 166 can be a thin oxide layer, e.g. about 2 nm to about 5 nm. Layer 168 can be a polysilicon layer which as shown in FIG. 19 can be patterned to form gate structures within region A and region B. Gate structures defined by layer 168 can be e.g. polysilicon gates or sacrificial polysilicon gates. Layer 166 and layer 164 can be of a common dielectric material. Layer 166 and layer 164 can be of different dielectric materials.

Referring to the semiconductor structure as shown in FIG. 19, the fins between region A and region B can include first and second different fin heights. Region A can have a first fin height and region B can have a second fin height greater than the first fin height. In the embodiment of FIG. 19, a fin height can be regarded as the spacing distance between a top elevation of layer 164 which can be a dielectric layer and a top elevation of substrate 102. In the embodiment of FIG. 19, fins within region B can have a common top elevation with fins of region B. In the embodiment of FIG. 19, layer 164 can have higher top elevation within region A than region B. Within region A, layer 160 can have a first elevation. Within region B, layer 164 can have a second elevation lower than the first elevation of layer 164. Fins within region A as shown in FIG. 19 can have a first height. Fins within region B as shown in FIG. 19 can have a second height greater than the first height.

In one embodiment, referring to FIG. 1, 12 or 19, region A can include FETs of a first polarity and region B can include FETs of a second polarity opposite of the first polarity. In such an embodiment, nFET and pFET regions can be provided that include device variability (mismatch) characteristics that have a higher level of correspondence to one another than would be provided in the case FETs of region A and region B include common fin heights. Referring to one embodiment, nFETs and pFETs of a semiconductor structure 10 can have different device variability characteristics. It was determined that pFETs can exhibit greater device variability than nFETs.

In one embodiment, device variability (mismatch) within a pFET region of a semiconductor structure 10 can be greater than device variability within an nFET region. Accordingly, the fabrication margins for nFET region FETS can be greater than fabrication margins for pFET region FETs. In one embodiment as set further herein fins of semiconductor structure to (FIGS. 1, 12, and 19) within a pFET region can have a taller fin height than fins within an nFET region. By making fins taller, device width can be made wider to increase a drive current of the device to thereby improve device variability. Referring to FIGS. 12 and 19, region A can be an nFET region and region B having a taller fin height can be a pFET region in one embodiment. In one embodiment, fabrication can remain common between region A and region B except for fin height. In one embodiment, semiconductor structure 10 as shown in FIGS. 1, 12 and 19 can be an SRAM semiconductor structure.

In one embodiment, region A and region B can be of a common polarity, e.g., each of region A and region B be nFET regions or in the alternative each of region A and region B can be pFET regions. In one example of such embodiment different fin heights throughout the regions can be included to provide an additional tuning knob for tuning of threshold voltage, Vt.

In one embodiment height of fins in the respective regions region A and region B can be established to achieve targeted threshold voltages within respective regions A and region B. In one embodiment, taller fins can have higher drive current, and accordingly lower threshold voltage, Vt. In the embodiment of FIGS. 12 and 19, region B can have a taller fin height than region A. In one embodiment, region A can be an HVT region and region B can be an RVT region having a common polarity (nFET or pFET) as region A. In one embodiment, region A can be an RVT region and region B can be an LVT region of a common polarity (nFET or pFET) with region A.

Each of the formed layers as set forth herein, e.g., layer 102, layer 106, layer 110, layer 114, layer 118, layer 122, layer 126, layer 130, layer 134, layer 140, layer 144, layer 148, layer 160, layer 164, and/or layer 168 can be formed by way of deposition using any of a variety of deposition processes, including, for example, physical vapor deposition (PVD), atomic layer deposition (ALD), chemical vapor deposition (CVD), sputtering, or other known processes, depending on the material composition of the layer. One or more of the layers set forth herein e.g. of layer 102, layer 106, layer 110, layer 114, layer 118, layer 122, layer 126, layer 130, layer 134, layer 140, layer 144, layer 148, layer 160, layer 164, and/or layer 168 can also be formed using material growth processes, e.g. thermal or epitaxial growth processes.

In one example, a protective mask layer as set forth herein, e.g., a mask layers for patterning e.g., layer 102, layer 106, layer 110, layer 114, layer 118, layer 122, layer 126, layer 130, layer 134, layer 140, layer 144, layer 148, layer 160, layer 164, and/or layer 168 as set forth herein may include a material such as, for example, silicon nitride, silicon oxide, or silicon oxynitride, and may be deposited using conventional deposition processes, such as, for example, CVD or plasma-enhanced CVD (PECVD). In other examples, other mask materials may be used depending upon the materials used in semiconductor structure. For instance, a protective mask layer may be or include an organic material. For instance, flowable oxide such as, for example, a hydrogen silsesquioxane polymer, or a carbon-free silsesquioxane polymer, may be deposited by flowable chemical vapor deposition (F-CVD). In another example, a protective mask layer may be or include an organic polymer, for example, polyacrylate resin, epoxy resin, phenol resin, polyamide resin, polyimide resin, unsaturated polyester resin, polyphenylene ether resin, polyphenylenesulfide resin or benzocyclobutene (BCB).

Removing material of a layer as set forth herein, e.g., layer 102, layer 106, layer 110, layer 114, layer 118, layer 122, layer 126, layer 130, layer 134, layer 140, layer 144, layer 148, layer 160, layer 164, and/or layer 168 can be achieved by any suitable etching process, such as dry or wet etching processing. In one example, isotropic dry etching may be used by, for example, ion beam etching, plasma etching or isotropic RIE. In another example, isotropic wet etching may also be performed using etching solutions selective to the material subject to removal.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include” (and any form of include, such as “includes” and “including”), and “contain” (and any form contain, such as “contains” and “containing”) are open-ended linking verbs. As a result, a method or device that “comprises”, “has”, “includes” or “contains” one or more steps or elements possesses those one or more steps or elements, but is not limited to possessing only those one or more steps or elements. Likewise, a step of a method or an element of a device that “comprises”, “has”, “includes” or “contains” one or more features possesses those one or more features, but is not limited to possessing only those one or more features. Furthermore, a device or structure that is configured in a certain way is configured in at least that way, but may also be configured in ways that are not listed.

The corresponding structures, materials, acts, and equivalents of all means or step plus function elements in the claims below, if any, are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of one or more aspects of the invention and the practical application, and to enable others of ordinary skill in the art to understand one or more aspects of the invention for various embodiments with various modifications as are suited to the particular use contemplated.

1. A semiconductor structure comprising:
a first region having fins;
a second region having fins;
an oxide layer extending between the first region and the second region,
wherein fins of the first region include a first fin height, and wherein fins of the second region include a second fin height different from the first fin height.

2. The semiconductor structure of claim 1, wherein the first fin height is defined as a spacing between a top of the fins of the first region and a top of the oxide layer of the first region.

3. The semiconductor structure of claim 1, wherein the first region and the second region have an opposite polarity.

4. The semiconductor structure of claim 1, wherein the first region and the second region have an opposite polarity, wherein the first region is a pFET region and wherein the first fin height is taller than the second fin height so that a device variability between the first region and the second region has a closer correspondence than a device variability in the case the first region and the second region have common fin heights.

5. The semiconductor structure of claim 1, wherein fins of the first region and fins of the second region have common top elevations.

6. The semiconductor structure of claim 1, wherein the oxide layer within the first region and the oxide layer within the second region have common top elevations.

7. The semiconductor structure of claim 1, wherein the first region and the second region have a common polarity, wherein the first fin height is taller than the second fin height so that the first region has a smaller threshold voltage than the second region.

8. A method for fabrication of a semiconductor structure comprising:
providing fins of a first region to include a first fin height;
providing fins of a second region to include a second fin height different than the first fin height; and
wherein the first region and the second region have an opposite polarity.

9. The method of claim 8, wherein the first fin height is defined as a spacing between a top of the fins of the first region and a top of an oxide layer of the first region.

10. The method of claim 8, wherein the first region and the second region have an opposite polarity.

11. The method of claim 8, wherein the first region and the second region have an opposite polarity, wherein the first region is a pFET region and wherein the first fin height is taller than the second fin height so that a device variability between the first region and the second region has a closer correspondence than a device variability in the case the first region and the second region have common fin heights.

12. The method of claim 8, wherein fins of the first region and fins of the second region have common top elevations.

13. The method of claim 8, wherein an oxide layer of the first region and an oxide layer of the second region have common top elevations.

14. The method of claim 8, wherein the first region and the second region have a common polarity, wherein the first fin height is taller than the second fin height so that the first region has a smaller threshold voltage than the second region.
